(19) United States
(12) Patent Application Publication
(10) Pub. No.: US 2018/0062562 A1
(43) Pub. Date: Mar. 1, 2018

(54) PHOTOVOLTAIC TILE

(71) Applicant: SUPERDOME SA, Luxembourg (LU)

(72) Inventor: Alexandre AZOULAY, PARIS (FR)

(21) Appl. No.: 15/555,332

(22) PCT Filed: Mar. 2, 2016
(86) PCT No.: PCT/EP2016/054444

§ 371 Date: Nov. 6, 2017

(30) Foreign Application Priority Data
Mar. 2, 2015 (FR) 1551756

(51) Int. Cl. H02S 20/25; H02S 40/34; H02S 40/36

(52) U.S. Cl. CPC H02S 20/25; H01L 31/02021; H02S 40/36; H02S 40/34

(57) ABSTRACT

A photovoltaic solar panel for forming a photovoltaic surface with adjacently arranged photovoltaic solar panels. The photovoltaic solar panel includes a body made of a rigid material, and first and second electrical connections. The first electrical connection includes an interposition element made of an elastomer material which, when interposed between the body of the photovoltaic solar panel and the body of an adjacent photovoltaic solar panel, participates in a securing process. during the laying of the photovoltaic solar panels, and absorbs relative movements caused by differential thermal expansion of elements of the photovoltaic solar panels during the use of the photovoltaic solar panels for the production of photovoltaic electricity.

### TECHNICAL BACKGROUND

The invention relates to a photovoltaic solar panel for forming a photovoltaic surface consisting of a plurality of adjacently arranged similar panels, used as basic tiles. Thus, they are traditionally referred to as photovoltaic tiles.

Such tiles are known, for example from document WO2011004092, which describes a rectangular tile that has edges overlapping by interlocking on its small sides and its large sides. Furthermore, an electrical connection of one tile to the adjacent tile, to connect it in series or in parallel, is done by electrical connectors that interlock when the overlapping edges are positioned to be assembled in turn by interlocking.

Also known from document WO00/30184 is a photovoltaic tile in which rubber is used to close the panel, which is in two parts. Also known from document US 2006/0266406 is a photovoltaic tile having an elastomeric body.

Nevertheless, these documents do not address one problem that occurs when the photovoltaic surface is subject to a temperature increase or temperature deviations, during the use of the surface to produce electricity. Some structures then experience losses of electrical contact between adjacent tiles, due to deformations that occur under the heat, in particular caused by the differential expansion experienced by the various materials of the tiles.

### Definition of the Invention

In order to resolve this problem, proposed here is a photovoltaic solar panel for forming a photovoltaic surface consisting of a plurality of such adjacently arranged photovoltaic solar panels, said panel comprising a body made of a rigid material, a first electrical connection means and a second electrical connection means, the first electrical connection means being configured to electrically connect said panel to an adjacent panel from among said adjacently arranged panels via the second electrical connection means of said adjacent panel, by mutual engagement of the first and second electrical connection means leading to securing of the body of the panel with the body of the adjacent panel and contact between electrical contractors of the first and second electrical connection means, characterized in that the first electrical connection means comprises an interposition element made of an elastomer material which, when interposed between the body of the panel and the body of the adjacent panel, participates in said securing process during the laying of the plurality of panels and absorbs relative movements caused by a differential thermal expansion of elements of the plurality of panels.

The invention may have some of the following advantageous features:

the mutual engagement of the first and second electrical connection means can be done in a direction transverse to the mean plane of the panel,

the interposition element may have an oblong general shape in the mean plane of the panel, elongated relative to an edge of the panel,

the interposition element can be made from rubber or Hytrel (registered trademark), or any other elastomeric, synthetic or natural material,

the interposition element may comprise two passages each allowing an electrical contactor to pass to establish the electrical connection between the panel and the adjacent panel,

the interposition element may comprise at least one female cylinder cooperating with a male cylinder made from a rigid material of the second electrical connection means, formed in the body of the panel,

the first and second electrical connection means can define a single electrical connection zone located on a portion of the elongated edge of the panel,

the first and second electrical connection means can define an electrical connection zone on the small sides of the panels, the latter being rectangular,

the mutual engagement can be done in a direction perpendicular to a surface for bearing of the adjacent panel on the panel, said bearing surface being oblique relative to the lower surface of the panel and the upper surface of the panel,

a photovoltaic surface of the panel can be planar or undulated.

The panel may additionally comprise an integrated converter converting direct current into alternating current, or conversely, supplying a direct current across its terminals.

The body may comprise a shell with two parts containing thermal insulation and electric energy management means.

### LIST OF FIGURES

The invention will be better understood, and other aims, features, details and advantages thereof will appear more clearly in the following explanatory description done in reference to the appended drawings given solely as an example illustrating one embodiment of the invention and in which:

FIG. 1 shows a general view of a tile according to one embodiment of the invention.

FIG. 2 shows a detailed view of the manufacture of the tile of FIG. 1.

FIG. 3A and FIG. 3) show the precise geometry of an element of the tile of FIG. 1.

FIG. 4 shows a sectional view of the placement of the element of FIGS. 3A and 3B.

FIG. 5 shows, in the same section, two tiles connected to one another.

### DETAILED DESCRIPTION OF THE INVENTION

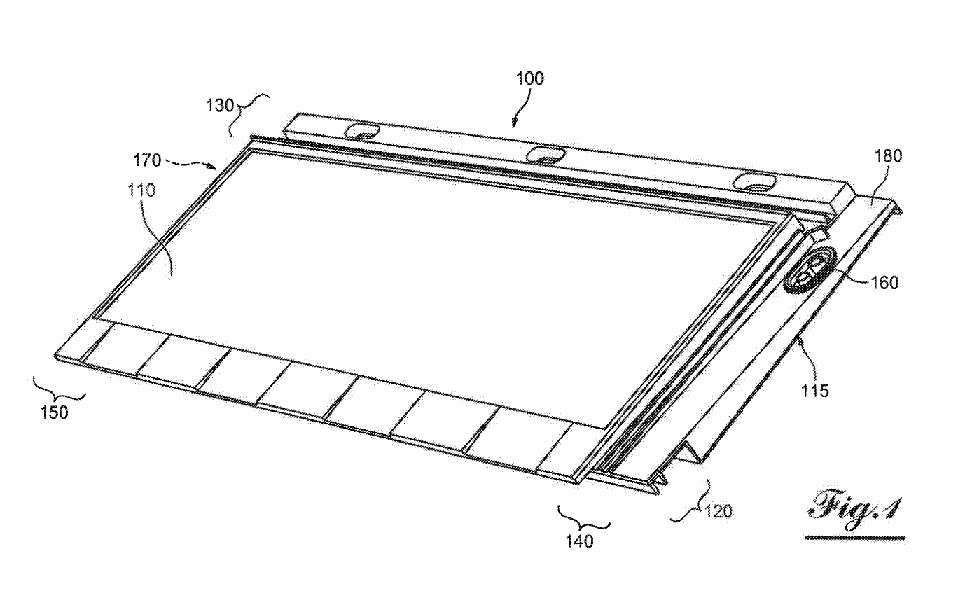

In reference to FIG. 1, a photovoltaic tile 100 is shown. It has a rectangular general shape, parallel to a laying plane on which it is configured to be laid. On an upper face of the tile 100 is a photovoltaic surface 110. On the opposite (lower) surface of the photovoltaic tile 100 is a laying surface 115, defining the laying plane, for placement on a structure such as the frame of the roof. The photovoltaic tile has a first overlapping edge on large side 120 and a second overlapping edge on large side 130, opposite the first edge 120. The tile additionally has a first overlapping edge on small side 140 and a second overlapping edge on small side 150 opposite the first edge 140.

The first and second edges 120 and 130 allow the assembly of tiles in a row of tiles extending parallel to the small side of the tile 100, by the imbrication of imbricating shapes present on the lower surface of the first edge 120, in imbricating shapes present on the upper face of the second edge 130.

The first and second edges 140 and 150 in turn allow the adjacent arrangement of identical photovoltaic tiles 100 in an alignment direction parallel to the large side of the tile 100, by imbrication in an imbricating shape present on the lower face of the second edge 150 in an imbricating shape present on the upper face of the first edge 140.

Thus, one is able to place an adjacent arrangement of similar photovoltaic tiles in two development directions perpendicular to one another, thus forming a photovoltaic surface made up of basic tiles.

The first overlapping edge on small side 140 comprises, on its upper surface, a first electrical connector 160 not far from a corner of the tile 100 and the overlapping edge on large side 130. The latter is surrounded by a bearing surface 180 extending over the entire length of the small side serving for the bearing of an adjacent photovoltaic tile on the photovoltaic tile 100. The second overlapping edge on small side 150 comprises a bearing surface opposite the bearing surface 180. This opposite bearing surface has, at a height corresponding to the height of the first electrical connector 160, a second electrical connector 170 (not visible, but shown in FIG. 5), intended to interact with the first electrical connector 160 during the placement of two photovoltaic tiles 100 arranged adjacently in the alignment direction parallel to the large side.

The first and second electrical connection means 160 and 170 define a single electrical connection zone located on a portion of the first overlapping edge on small side 140 and on a corresponding portion of the second overlapping edge on small side 150.

The body of the tile comprises a shell with two parts, advantageously made from rigid organic composite materials, and containing, in some embodiments, thermal insulating means, and optionally means for managing and optimizing the produced electric energy, such as an integrated converter converting direct current into alternating current or remote control and maintenance means of the tile.

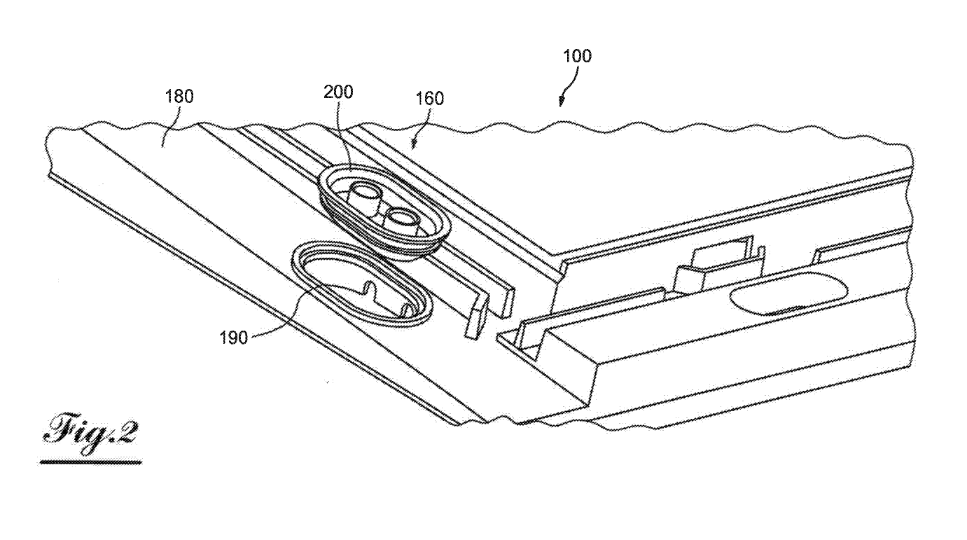

FIG. 2 shows a view of the assembly of the first electrical connector 160. One can see the bearing surface 180, which is traversed by an oblong opening 190, elongated parallel to the small side of the photovoltaic tile 100. The opening 190 allows the placement of an interposition and connection element 200, made from rubber or another elastomeric material, or another flexible elastic material, for example a synthetic material, or a natural material. Hytrel is also used in one particular embodiment, for its simultaneous elastomeric and thermoplastic properties. An appropriate grade of Hytrel will be chosen based on the expected temperature variations, as well as mechanical stresses.

In the view of FIG. 2, the interposition and connection element 200 is shown during laying, aligned with the opening 190 at a distance therefrom, above the bearing surface 180.

The interposition and connection element 200 also has an oblong general shape in a plane parallel to the bearing surface 180 and dimensions allowing it to be placed in the opening 190, by embedding. More specifically, the circumference of the interposition and connection element 200 has a groove which, during the placement in the opening 190, receives a rib of the body of the photovoltaic tile 100, for securing of the interposition and connection element 200 to the body of the photovoltaic tile 100.

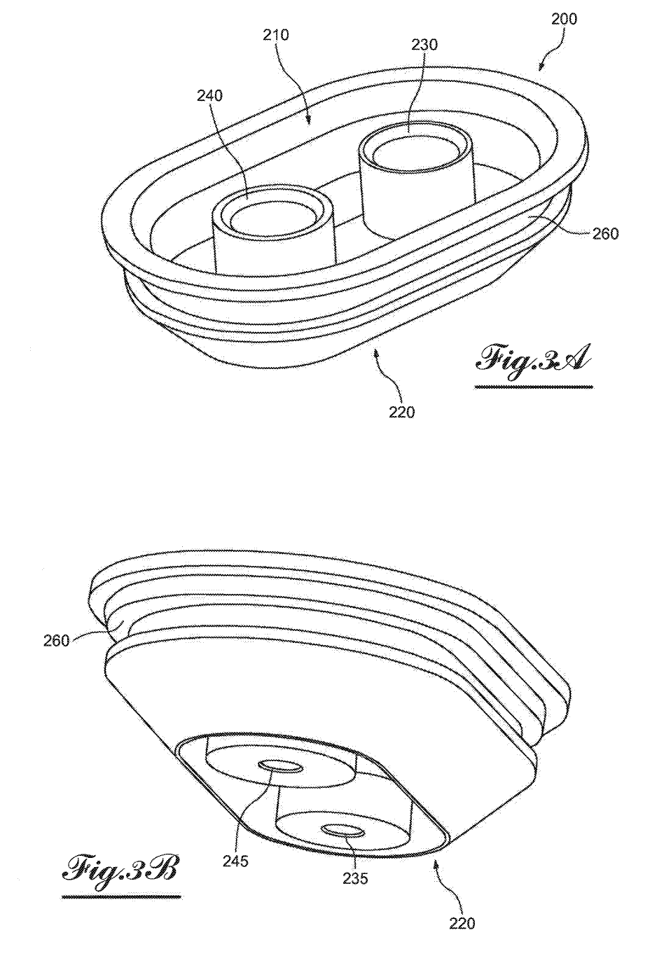

FIG. 3A and FIG. 3B show a more detailed view of the geometry of the interposition and connection element 200. The latter includes an open mouth 210 on one side of the plane of the oblong shape. On the other side of the plane of the oblong shape, there is a lower bottom 220, which is essentially solid. On the circumference of the oblong shape, parallel to the plane thereof, a groove 260 goes around the interposition and connection element 200. Furthermore, two embedding cylinders 230 and 240, aligned parallel to the elongation direction of the oblong shape, are present in the inner volume of the interposition and connection element 200. They are fastened on the lower bottom 220, have a generatrix perpendicular to the plane of the oblong shape, and have a mouth open on the side of the wide upper mouth 210. Opposite their open mouth, these embedding cylinders 230 and 240 have narrow passages for electrical contactors 235 and 245.

The cylinders 230 and 240 are for example cylinders of revolution, and the passages 235 and 245 are made up of circular openings at the center of a closed surface making up a straight section of the cylinders 230 and 240.

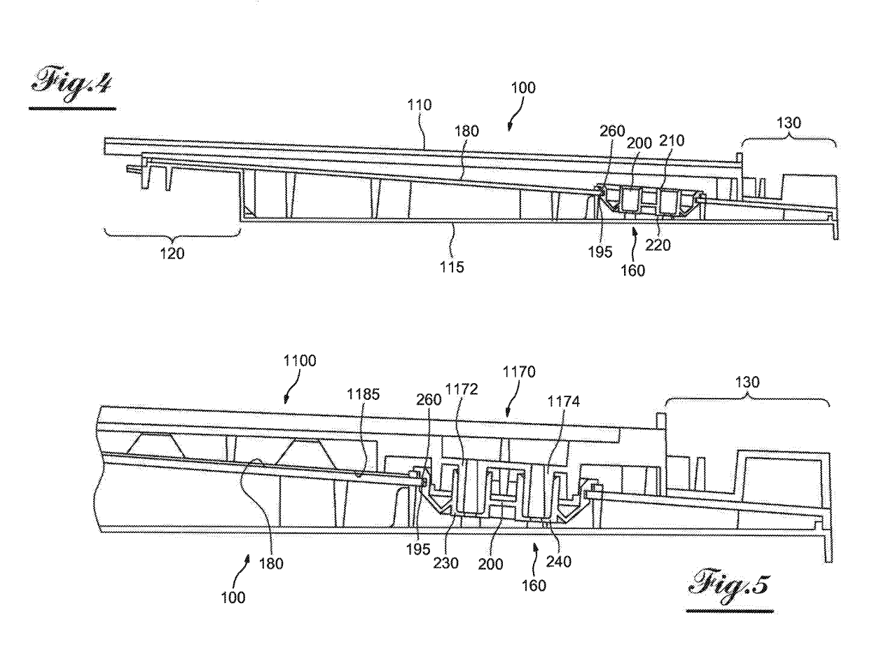

FIG. 4 shows, in sectional view, the positioning of the interposition and connection element 200 in the body of the photovoltaic tile 100. In this figure, one can see the fastening rib 195, which is inserted in the fastening groove 260 of the interposition and connection element 200. The open mouths of the embedding cylinders 230 and 240 are arranged on the side of the photovoltaic surface 110, while the passages for electrical contactors 235 and 245 are placed on the side of the placement surface 115.

One can see in this figure that the bearing surface 180 is sloped relative to the upper and lower surfaces of the tile, here the laying surface 115 and the photovoltaic surface 110. Seen in the sectional view of the figure, the bearing surface 130 approaches the laying surface 115 upon approaching the second overlapping edge on large side 130, and moving away from the first overlapping edge on large side 120.

FIG. 5 shows a detailed sectional view of a set of two tiles connected to one another using the first electrical connector 160 and second electrical connector 170. The view is shown in the same cutting plane as FIG. 4. The references used for the second photovoltaic tile correspond to the references used for the first photovoltaic tile, incremented by 1000.

The second connector 1170 comprises two embedding cylinders 1172 and 1174 formed in the material of the body of the photovoltaic tile 1100. These two embedding cylinders 1172 and 1174 are imbricated inside the embedding cylinders 230 and 240 of the interposition and connection element 200.

The opposite bearing surface 1185 of the second photovoltaic tile 1100 is in contact with the bearing surface 180 of the first photovoltaic tile 100.

The electrical connection is done by electrical contactors, not shown, placed in contact owing to the imbrication of the embedding cylinders 230 and 240 on one side and 1172 and 1174 on the other. Two separate electrical contacts are established, one using embedding cylinders 230 and 1172, and the other using embedding cylinders 240 and 1174. The cylinders 230 and 240 are female cylinders cooperating with the male cylinders 1172 and 1174 made from a rigid material formed in the body of the panel.

The passages 235 and 245 of the interposition and connection element 200 each allow an electrical contactor to pass to establish the electrical connection between the panel and the adjacent panel.

More generally, the first and second electrical connection means 160 and 170 are mutually engaged with respect to one another, and this engagement is done in a direction perpendicular to the bearing surface 180 and therefore transverse to the mean plane of the tile 100, or its laying plane.

The interposition and connection element 200 is thus interposed between the body of the tile and the body of the adjacent tile and participates in securing two tiles, while absorbing, during use of the tiles to produce photovoltaic electricity, relative movements caused by a differential thermal expansion of tile elements.

The invention is not limited to the described embodiment, but extends to all alternatives within the context of the scope of the claims. It will in particular be specified that the photovoltaic surface 110 of the panel may not be planar, but instead undulated, without altering the mechanical intellectual connection principles on the edges of the tile.

1. A photovoltaic solar panel for forming a photovoltaic surface consisting of a plurality of the photovoltaic solar panels, adjacently arranged wherein the photovoltaic panel comprises:
a body made of a rigid material, and
first electrical connection means and second electrical connection means, wherein
the first electrical connection means is configured to electrically connect the photovoltaic solar panel to an adjacent photovoltaic solar panel via the second electrical connection means of the adjacent photovoltaic solar panel, by mutual engagement of the first and second electrical connection means leading to securing of the body of the photovoltaic solar panel with the body of the adjacent photovoltaic solar panel and contact between electrical contactors of the first and second electrical connection means, and
the first electrical connection means comprises an interposition element of an elastomer which, when interposed between the body of the photovoltaic solar panel and the body of the adjacent photovoltaic solar panel, participates in a securing process during joining of the the photovoltaic solar panel and the adjacent photovoltaic solar panel, and absorbs relative movements caused by differential thermal expansion of elements of the photovoltaic solar panel and the adjacent photovoltaic solar panel.

2. The photovoltaic solar panel according to claim 1, wherein the mutual engagement of the first and second electrical connection means lies along a direction transverse to a median plane of the photovoltaic solar panel.

3. The photovoltaic solar panel according to claim 2, wherein the interposition element has an oblong shape in the median plane of the photovoltaic solar panel, elongated relative to an edge of the photovoltaic solar panel.

4. The photovoltaic solar panel according to claim 1, wherein the interposition element is a synthetic or natural elastomer.

5. The photovoltaic solar panel according to claim 1, wherein the interposition elements comprises two passages, wherein each passage passes an electrical contactor establishing an electrical connection between the photovoltaic solar panel and the adjacent photovoltaic solar panel.

6. The photovoltaic solar panel according to claim 1, wherein
the interposition element comprises a male cylinder and at least one female cylinder cooperating with the male cylinder, and
the male cylinder is a rigid material that is part of the second electrical connection means and is located in the body of the photovoltaic solar panel.

7. The photovoltaic solar panel according to claim 3, wherein the first and second electrical connection means define a single electrical connection zone located on a portion of the edge of the photovoltaic solar panel.

8. The photovoltaic solar panel according to claim 1, wherein
the photovoltaic solar panel is rectangular in shape and has two relatively longer sides and two relatively shorter sides, and
the first and second electrical connection means define an electrical connection zone on the relatively shorter sides of the photovoltaic solar panel.

9. The photovoltaic solar panel according to claim 1, wherein
the mutual engagement extends in a direction perpendicular to a bearing surface for bearing the adjacent photovoltaic solar panel, on the photovoltaic solar panel, and
the bearing surface is oblique to a lower surface of the photovoltaic solar panel and an upper surface of the photovoltaic solar panel.

10. The photovoltaic solar panel according to claim 1, wherein a light-incident surface of the photovoltaic solar panel is planar or undulated.

11. The photovoltaic solar panel according to claim 1, comprising an integrated converter converting direct current into alternating current, or supplying direct current.

12. The photovoltaic solar panel according to claim 1, wherein the body comprises a shell with two parts and containing thermal insulation and electric energy management means.
